(19) United States
(12) Patent Application Publication
(10) Pub. No.: US 2024/0121489 A1
(43) Pub. Date: Apr. 11, 2024

(54) BASE OF IMAGE ACQUISITION MODULE, IMAGE ACQUISITION MODULE, AND CAMERA MODULE

(71) Applicant: SHENZHEN JSL ELECTRONICS CORPORATION LIMITED, Shenzhen, Guangdong (CN)

(72) Inventor: Dong LI, Shenzhen (CN)

(21) Appl. No.: 18/263,841

(22) PCT Filed: Aug. 29, 2022
(86) PCT No.: PCT/CN2022/115409

§ 371 Date: Aug. 1, 2023

(30) Foreign Application Priority Data
Aug. 3, 2021 (CN) 202110885902.8
May 12, 2022 (CN) 202210514520.9

(51) Int. Cl. H04N 23/45; H04N 23/51; H04N 23/52; H04N 23/55; H04N 25/11

(52) U.S. Cl. CPC H04N 23/45; H04N 23/51; H04N 23/52; H04N 23/55; H04N 25/11

(57) ABSTRACT

The present disclosure relates to a base of an image acquisition module, an image acquisition module, and a camera module. The image acquisition module comprises a base and an image sensor. The base comprises a base body, and an electric conductor that is injection molded on the base body. The base is used for assembling a lens base. The image sensor is arranged on the base body and is electrically connected to the electric conductor.

### CROSS-REFERENCE TO RELATED APPLICATIONS

This application is an U.S. national phase application under 35 U.S.C. § 371 based upon international patent application PCT/CN2022/115409 filed on Aug. 29, 2022, which itself claims priority of Chinese Patent Application No. 2021108859028, filed on Aug. 3, 2021 and Chinese Patent Application No. 2022105145209, filed on May 12, 2022, the contents of the above identified applications are hereby incorporated herein in their entireties by reference.

### TECHNICAL FIELD

The present disclosure relates to the technical field of optoelectronic equipment, in particular to a base of an image acquisition module, an image acquisition module, and a camera module.

### BACKGROUND

In related technology, during the processing of a camera module, FPC (Flexible Printed Circuit) is generally used as a substrate, and electronic components such as resistors, capacitors, connectors, driver or storage chips, etc. are mounted on a surface of the substrate and fixed by welding, then an image sensor is mounted on the substrate through a special packaging equipment, and an electrical connection between the image sensor and the substrate is achieved by gold wires or solder balls, then a filter, a lens holder, etc. are assembled to the substrate to obtain the camera module.

However, a flatness of the surface of the FPC is generally poor. When the image sensor, the lens holder, and other structures are assembled to the FPC as the substrate, an assembly accuracy of the camera module is difficult to control and the defective rate is high.

### SUMMARY

Accordingly, it is necessary to provide a base of an image acquisition module, an image acquisition module, and a camera module to improve yield of product.

An image acquisition module includes a base including a base body and a conductor injection-molded on the base body, the base being configured to assemble a lens holder; and an image sensor provided on the base and electrically connected to the conductor.

In one of the embodiments, the base includes opposite first and second sides, the base is provided with a through hole extending from the first side to the second side, the first side is configured to assemble the lens holder, and the image sensor is provided on the second side and covers one end of the through hole.

In one of the embodiments, the second side is provided with a first mounting groove, the through hole extends to a bottom of the first mounting groove, and the image sensor is embedded in the first mounting groove.

In one of the embodiments, the second side is provided with a second mounting groove spaced apart from the first mounting groove, the image acquisition module includes an electronic component provided in the second mounting groove and electrically connected to the conductor.

In one of the embodiments, the base includes opposite first and second ends, the first end and the second end are located between the first side and the second end, the conductor is exposed to the first mounting groove, the second mounting groove, the first end, and the second end.

In one of the embodiments, the first side is provided with a third mounting groove, the through hole extends to a bottom of the third mounting groove, the image acquisition module includes a filter embedded in the third mounting groove and covering the other end of the through hole.

In one of the embodiments, the base is provided with a limiting structure on the first side, the limiting structure is configured to assemble and position with the lens holder, and the third mounting groove is provided on the limiting structure.

In one of the embodiments, the conductor includes a wire substrate formed by bending and a plating layer plated on a surface of the wire substrate, the plating layer is made of at least nickel and gold.

A camera module includes a lens holder and the above-mentioned image acquisition module.

In one of the embodiments, the lens holder includes a lens barrel and a mounting base sleeved on the lens barrel, and the mounting base is connected to the base.

In the above-mentioned image acquisition module and the camera module, the conductor configured to be electrically connected to the image sensor is injection molded on the base, and the lens holder can be assembled on the base. Compared with the FPC, the base has stronger structural rigidity, and a surface flatness, a position accuracy, etc. of the base can be easily ensured. When the image sensor and the lens holder are assembled on the base, higher assembly accuracy can be obtained. Compared with the structure in which the image sensor is packaged on the FPC and the lens holder is stacked on the FPC in the related art, the above-mentioned image acquisition module has a higher integration, which can reduce the investment in high-precision production equipment, and has fewer production processes, lower quality control difficulties and lower costs. Since the image sensor is electrically connected to the conductor that is injection molded on the base, this configuration simplifies the assembly and electrical connection process of the image sensor and the base, and can ensure the reliability of the electrical connection between the image sensor and the base. The conductor may be made of lower-cost materials such as the copper foil. Compared with the high-purity gold wire of FPC, the conductor has better structural stability and lower cost, and the reliability of the electrical connection of the image sensor can be ensured.

An image acquisition module includes a base including a base body and a conductor integrally formed with the base body, the base being configured to assemble a lens holder; and an image sensor provided on the base and electrically connected to the conductor.

In one of the embodiments, the base includes opposite first and second sides, the base is provided with a through hole extending from the first side to the second side, the first side is configured to assemble the lens holder, and the image sensor is provided on the second side and covers one end of the through hole.

In one of the embodiments, the second side is provided with a first mounting groove, the through hole extends to a bottom of the first mounting groove, and the image sensor is embedded in the first mounting groove.

In one of the embodiments, the second side is provided with a second mounting groove spaced apart from the first mounting groove, the image acquisition module includes an electronic component provided in the second mounting groove and electrically connected to the conductor.

In one of the embodiments, the first side is provided with a third mounting groove, the through hole extends to a bottom of the third mounting groove, the image acquisition module includes a filter embedded in the third mounting groove and covering the other end of the through hole.

In one of the embodiments, the base is provided with a positioning boss on the first side, the positioning boss is configured to assemble and position a positioning groove of the lens holder, the third mounting groove is provided on the positioning boss.

In one of the embodiments, the conductor comprises a wire substrate formed by bending and a plating layer plated on a surface of the wire substrate, the plating layer is made of at least nickel and gold.

A camera module includes a lens holder and the above-mentioned image acquisition module.

A base of an image acquisition module includes a base body and a conductor injection-molded on the base body, a first side of the base body is configured to assemble a lens holder, a second side of the base body opposite to the first side is configured to dispose an image sensor, and the conductor is configured to be electrically connected to the image sensor and an external circuit.

In the above-mentioned base of an image acquisition module, the image acquisition module, and the camera module, the conductor configured to be electrically connected to the image sensor is integrally formed with the base, and the lens holder can be assembled on the base. Compared with the FPC, the base has stronger structural rigidity, and a surface flatness, a position accuracy, etc. of the base can be easily ensured. When the image sensor and the lens holder are assembled on the base, higher assembly accuracy can be obtained. Compared with the structure in which the image sensor is packaged on the FPC and the lens holder is stacked on the FPC in the related art, the above-mentioned image acquisition module has a higher integration, which can reduce the investment in high-precision production equipment, and has fewer production processes, lower quality control difficulties and lower costs. Since the image sensor is electrically connected to the conductor that is integrally formed with the base, this configuration simplifies the assembly and electrical connection process of the image sensor and the base, and can ensure the reliability of the electrical connection between the image sensor and the base. The conductor may be made of lower-cost materials such as the copper foil. Compared with the high-purity gold wire of FPC, the conductor has better structural stability and lower cost, and the reliability of the electrical connection of the image sensor can be ensured.

### BRIEF DESCRIPTION OF THE DRAWINGS

In order to illustrate the embodiments of the present disclosure more clearly, the drawings used in the embodiments will be described briefly. Apparently, the following described drawings are merely for the embodiments of the present disclosure, and other drawings can be derived by those of ordinary skill in the art without any creative effort.

FIG. 1 is a schematic view of a camera module in the related art.

FIG. 2 is a schematic view of another camera module in the related art.

FIG. 3 is an exploded view of a camera module according to an embodiment.

FIG. 4 is a bottom view of an image acquisition module according to an embodiment.

FIG. 5 is a schematic diagram of a processing method of an image acquisition module according to an embodiment.

FIG. 6 is a schematic diagram of a processing method of an image acquisition module according to another embodiment.

FIG. 7 is a cross-sectional view of a portion of an image acquisition module according to an embodiment.

FIG. 8 is a schematic view of a camera module according to an embodiment.

FIG. 9 is a schematic view of the camera module shown in FIG. 8 viewed from another aspect.

FIG. 10 is a cross-sectional view of another portion of an image acquisition module according to an embodiment.

FIG. 11 is a top view of an image acquisition module according to an embodiment.

### REFERENCE NUMERALS

11, flexible circuit board; 12, image sensor 13, filter;
14, mounting base; 15, lens barrel; 16, connector;
17, electronic component; 18, gold wire; 19, solder ball;
100, lens holder; 110, lens barrel; 120, mounting base;
121, positioning structure; 300, image acquisition module; 301, wire substrate;
310, base; 310a, first side 310b; second side;
310c, through hole; 310d, first mounting groove; 310e, second mounting groove;
310f, first end; 310g, second end; 310h, third mounting groove;
311, base body; 311a, limiting structure; 313, conductor;
320, image sensor; 330, electronic component; 340, conductive particle;
350, filter.

### DETAILED DESCRIPTION OF THE EMBODIMENTS

In order to facilitate the understanding of the present disclosure, the present disclosure is described more comprehensively below with reference to the relevant accompanying drawings. Preferred embodiments of the present disclosure are shown in the accompanying drawings. However, the present disclosure may be implemented in many different forms and is not limited to the embodiments described herein. On the contrary, the purpose of providing these embodiments is to make the public content of the present disclosure more thoroughly and comprehensively understood.

It should be noted that when an element is referred to as being “fixed to” another element, it can be directly fixed to another element or intervening elements may also be present. When an element is referred to as being “connected to” another element, it can be directly connected to another element or intervening elements may also be present. The terms “vertical”, “horizontal”, “left”, “right”, and similar expressions are used herein for purposes of illustration only.

Unless otherwise defined, all technical and scientific terms used herein have the same meanings as those commonly understood by those skilled in the technical field of the present disclosure. The terms used in the specification of the present disclosure herein are only for the purpose of describing specific embodiments, and are not intended to limit the present disclosure. As used herein, the term “and/or” includes any and all combinations of one or more related listed items.

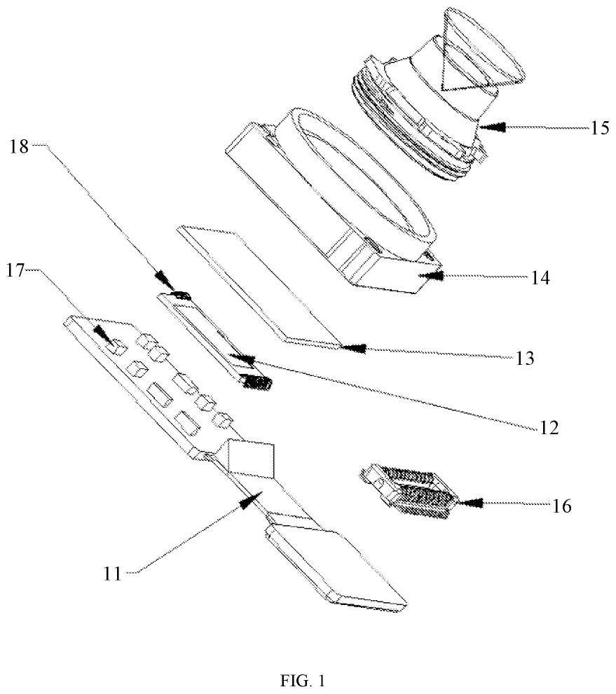

Referring to FIG. 1, in the related art, a COB (Chip on Board) type camera module generally includes a flexible circuit board 11, an image sensor 12, a filter 13, a mounting base 14, a lens barrel 15, and a connector 16. The flexible circuit board 11 is provided with electronic components 17 such as capacitors and resistors. The image sensor 12 is stacked on a side of the flexible circuit board 11 and is electrically connected to the flexible circuit board 11 through gold wires 18. The mounting base 14 is stacked on the flexible circuit board 11 and covers the image sensor 12. The lens barrel 15 is connected to the mounting base 14, and a lens group for converging light to the image sensor 12 is provided in the lens barrel 15. The filter 13 is provided in the mounting base 14 and is located between the lens group and the image sensor 12, and the filter 13 is configured to filter infrared light to improve the quality of shooting. The connector 16 is electrically connected to the flexible circuit board 11, and the camera module can be electrically connected to an external circuit such as a motherboard of a mobile phone through the connector 16, so as to achieve a communication connection between the camera module and the motherboard.

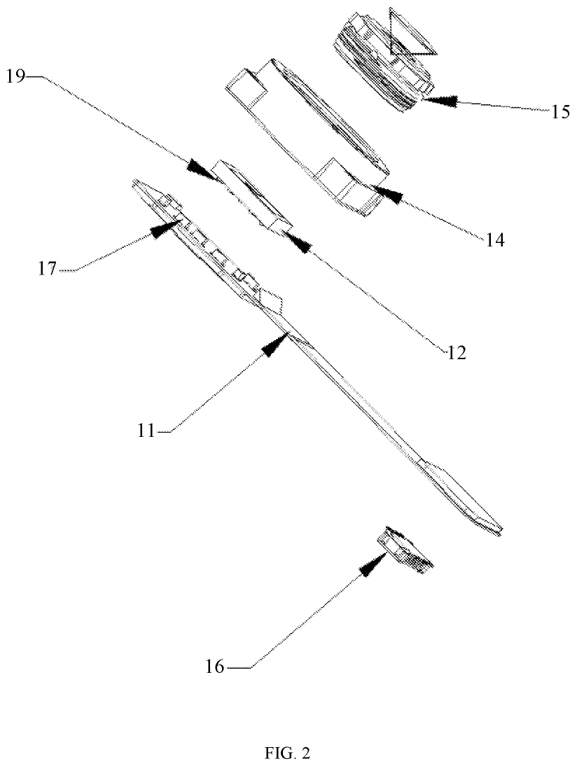

Referring to FIG. 2, in the related art, a CSP (Chip Scale Package) type camera module generally includes a flexible circuit board 11, an image sensor 12, a mounting base 14, a lens barrel 15, and a connector 16. The flexible circuit board 11 is provided with electronic components 17 such as capacitors and resistors. Different from the COP type camera module, the image sensor 12 of the CSP type camera module is generally electrically connected to the flexible circuit board 11 by solder balls 19.

The combination of the lens barrel 15 and the mounting base 14 may be referred to as a lens holder. The lens barrel 15 and the mounting base 14 can be assembled, for example, the lens barrel 15 and the mounting base 14 can be screwed together. The lens barrel 15 can also be integrally formed with the mounting base 14.

With regard to the above COB or CSP type camera module, during the processing process of the camera module, the flexible printed circuit 11 is generally used as a substrate, and the electronic components 17 such as resistors, capacitors, connectors, driver or storage chips, etc. and connector 16 are mounted on a surface of the substrate and fixed by welding, then the image sensor 12 is mounted on the substrate through a special packaging equipment, and an electrical connection between the image sensor 12 and the substrate is achieved by the gold wires 18 or the solder balls 19, then the filter 13, the mounting base 14, and the lens barrel 15, etc. are assembled to the substrate to obtain the camera module.

However, a flatness of the surface of the flexible circuit board 11 is generally poor. When the image sensor 12, the lens holder, and other structures are assembled to the flexible circuit board 11 as the substrate, an assembly accuracy of the camera module is difficult to control and the defective rate is high.

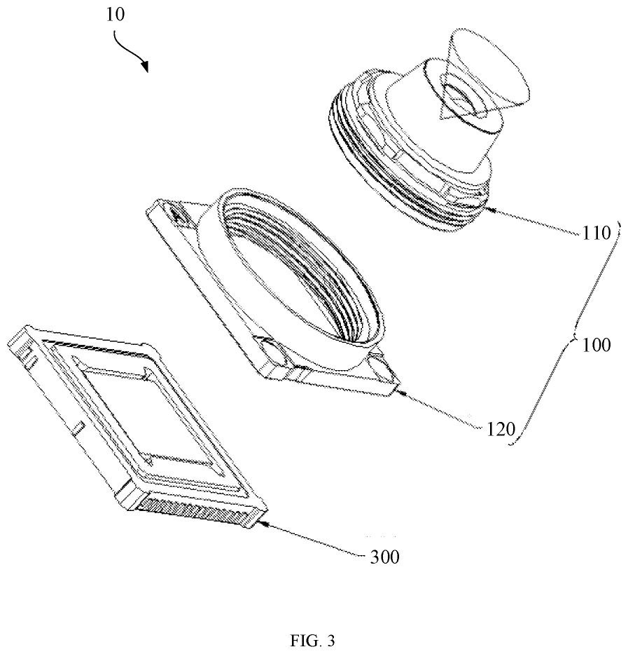

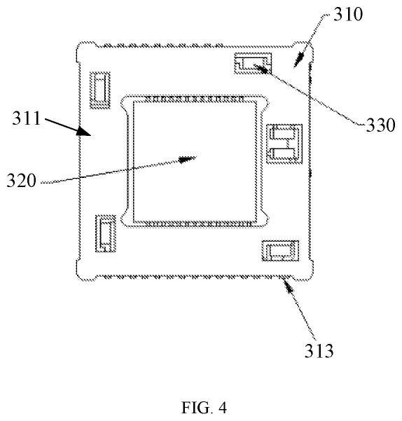

Referring to FIG. 3 and FIG. 4, the present disclosure provides a camera module 10. The camera module 10 includes a lens holder 100 and an image acquisition module 300. The lens holder 100 is assembled to the image acquisition module 300. The image acquisition module 300 includes a base 310 and an image sensor 320. The base 310 includes a base body 311 and a conductor 313 injection-molded on the base body 311, and the base 310 is configured to assemble the lens holder 100. The lens holder 100 may include a lens barrel 110 and a mounting base 120 connected to the lens barrel 110. The mounting base 120 is assembled on the base 310, and the lens barrel 110 is provided with a lens group for converging light. The image sensor 320 is provided on the base body 311 and is electrically connected to the conductor 313.

In some embodiments, the base 310 is substantially in a shape of a rectangular block. The base 310 includes a plurality of spaced-apart conductors 313, and the plastic material of the base 310 can ensure electrical insulation between adjacent conductors 313. An end or a portion of the conductor 313 configured to be electrically connected to an external device may be exposed to an outside. In some embodiments, the conductor 313 uses copper as base material, i.e., as a main part of a conductive circuit, and its surface can be plated with a metal coating to improve surface wear resistance and electrical conductivity. In the embodiment of the present disclosure, the conductor 313 is configured to be electrically connected to the image sensor 320 of the camera module 10, and can be configured to be electrically connected to external circuit boards such as the motherboards of electronic devices such as mobile phones and tablet computers, so as to achieve a communication connection between the camera module 10 and the external motherboard. When copper is configured as the base material of the conductor 313, a cost is relatively low compared with gold wires, silver wires, and the like. Certainly, in other embodiments, the base material of the conductor 313 may also be silver wire or other alloy materials.

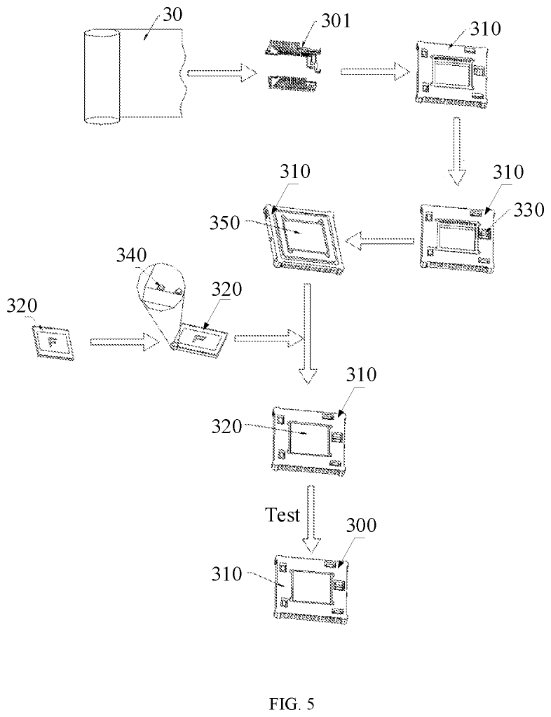

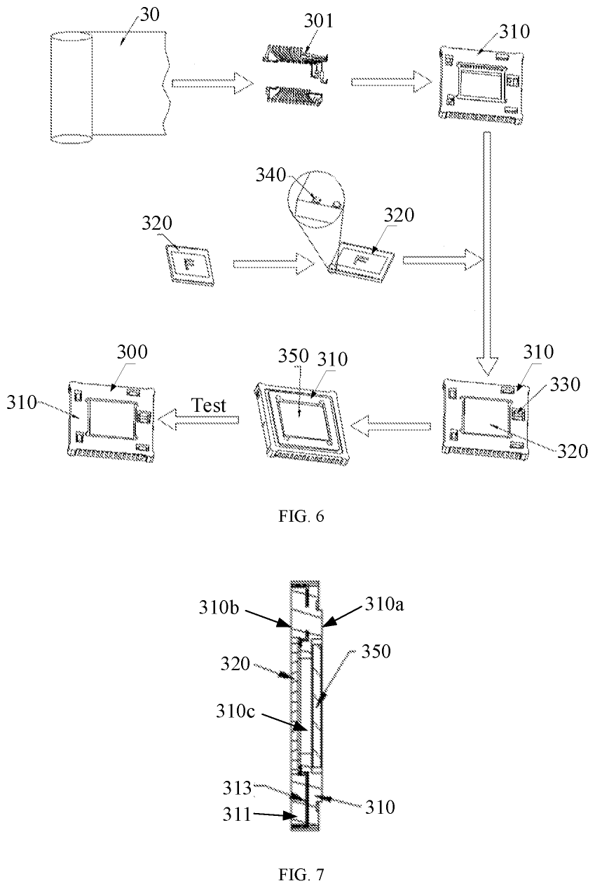

Referring to FIG. 5 and FIG. 6, in the embodiment where the base material of the conductor 313 is copper, a copper foil 30 can be punched and bent using a cutting die to obtain a wire substrate 301, which is approximately curved. More than two wire substrates 301 are provided. One end of the wire substrate 301 may be configured to be electrically connected to the image sensor 320, and the other end of the wire substrate 301 may be configured to be connected to an external circuit. Certainly, other connection points can be provided between both ends of the wire substrate 301, and the connection points can be configured to be electrically connected to electronic components 330 of the camera module 10 such as resistors, capacitors, and driver or storage chips, etc., so as to achieve a normal operation of the camera module 10.

After the copper foil 30 is punched and bent into the wire substrate 301, a plating layer can also be formed on a surface of the wire substrate 301 to improve surface properties, such as improving a wear resistance and an electrical conductivity of the surface of the wire substrate 301, thereby obtaining a surface-modified conductor 313. The material of the plating layer includes at least nickel and gold. In some embodiments, the material of the plating layer may also include tin. Certainly, it can be understood that the plating layer on the surface of the conductor 313 can be omitted.

In some embodiments, the plating layer can be formed on the surface of the wire substrate 301 by a spot plating process. The spot plating process is a type of electroplating process in which the plating solution is ejected at high pressure from anode water bladder to a plating area, and metal ions in the plating solution are deposited on the plating area under an action of an electric field to form the plating layer. The accurate plating area can be obtained by the spot plating process, that is, a designated position can be electroplated by the spot plating process.

After the conductor 313 is formed, through an insert molding process, the conductor 313 can be placed in a preset mold cavity, then molten plastic is injected into the mold cavity. After the plastic is cooled, the base 310 can be formed. The conductor 313 of the base 310 is wrapped in plastic material. In some embodiments, both ends of the conductor 313 may be exposed from the base 310, so as to facilitate the electrical connection between the conductor 313 and the image sensor 320, and facilitate the electrical connection between the conductor 313 and the external circuit. In other embodiments, the conductor 313 does not need to be exposed from the injection molded base 310, and a part plastic of the base 310 covering the conductor 313 can be removed by melting or other means during the assembly of the image sensor 320 and the conductor 313.

In other embodiments, the conductor 313 may be integrally formed with the base 310 using other manners, for example, the conductor 313 may be formed on the base 310 by powder metallurgy or the like.

Referring to FIG. 7, the base 310 includes opposite first and second sides 310a, 310b. The base 310 is provided with a through hole 310c, a cross-section of the through hole 310c may be rectangular, and the through hole 310c extends from the first side 310a to the second side 310b. The first side 310a is configured to assemble the lens holder 100, and the image sensor 320 is provided on the second side 310b and covers one end of the through hole 310c. Ambient light can be incident from the lens barrel 110 of the lens holder 100, and then incident from the through hole 310c to the image sensor 320 after passing through the lens group in the lens barrel 110, and the image sensor 320 can convert a light signal into an electrical signal.

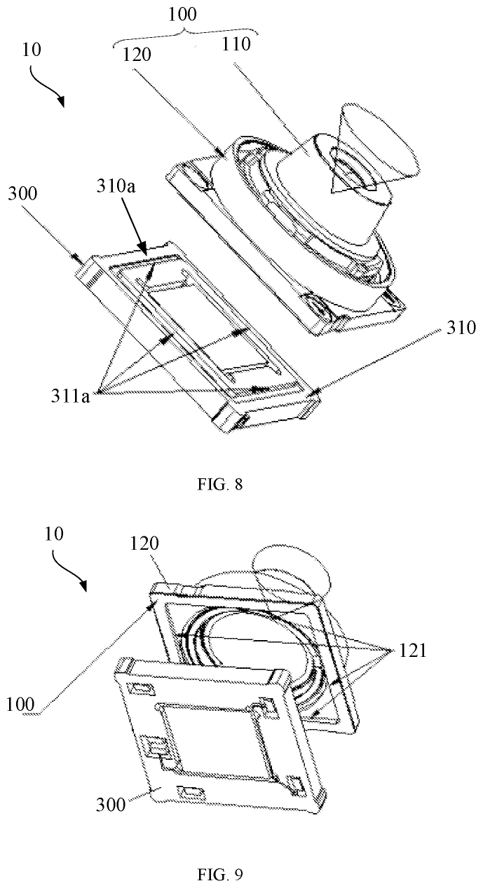

Referring to FIG. 8, in some embodiments, after the base 310 is injection molded, a limiting structure 311a may be directly molded or processed on the first side 310a of the base 310. The limiting structure 311a is configured to mount and position the lens holder 100 on the base 310. Referring to FIG. 9, the mounting base 120 of the lens holder 100 may also be provided with a positioning structure 121 configured to cooperate with the limiting structure 311a of the base 310. Exemplary, the base 310 is provided with a positioning boss on the first side 310a, and the mounting base 120 of the lens holder 100 is provided with a positioning groove. During the assembly process of the lens holder 100 and the base 310, the lens holder 100 can be assembled and positioned through the cooperation of the positioning boss and the positioning groove, so as to improve the efficiency of assembly. In other embodiments, the limiting structure 311a may be two or more posts or bumps, and the positioning structure 121 may be two or more grooves adapted to the posts or bumps. In some implementations, the lens holder 100 can be assembled to the image acquisition module 300 by HM (Holder Mount, mounted on the base 310) equipment, and then the position of the lens holder 100 on the base 310 is manually adjusted to achieve clear focus of the camera module 10. In some other embodiments, the lens holder 100 can also be automatically adjusted to achieve clear focus through an AA (Active Alignment) device.

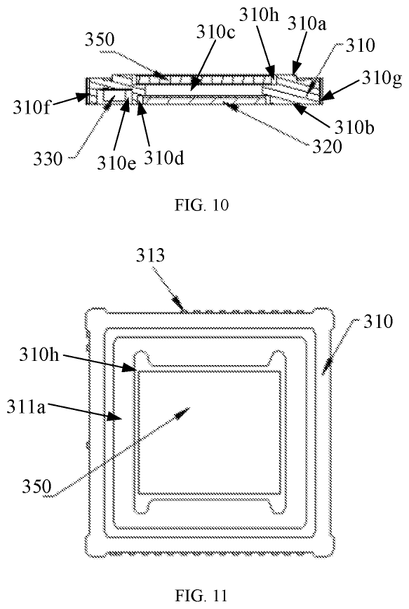

Referring to FIG. 10 and FIG. 11, in some embodiments, the second side 310b is provided with a first mounting groove 310d, that is, a side of the base 310 away from the lens holder 100 is provided with the first mounting groove 310d. The through hole 310c extends to a bottom of the first mounting groove 310d, that is, the through hole 310c is in communication with the first mounting groove 310d. The image sensor 320 is embedded in the first mounting groove 310d. A shape of the first mounting groove 310d cooperates with a shape of the image sensor 320. For example, in the embodiment where the image sensor 320 is in the shape of a rectangular block, the first mounting groove 310d is substantially rectangular, that is, the cross-section of the first mounting groove 310d is rectangular. The first mounting groove 310d facilitates the assembly and positioning of the image sensor 320 on the base 310.

Referring to FIG. 5 again, in the process of assembling the image sensor 320 on the base 310, conductive particles 340 may be provided on the image sensor 320 first, and the conductive particles 340 are configured to achieve an electrical connection between the image sensor 320 and the conductor 313. In some embodiments, a gold wire ball welding machine may be used to provide the conductive particles 340 at positions of the image sensor 320 for the electrical connection, that is, the image sensor 320 is planted with gold ball particles, and can be cleaned and dried by centrifugal cleaning, so as to achieve the electrical connection between the image sensor 320 and the conductor 313 through the gold ball particles, and to ensure the reliability of the electrical connection.

Referring to FIG. 6 again, in some other embodiments, a laser solder ball welding machine may be used to provide conductive particles 340 at positions of the image sensor 320 for electrical connection, that is, solder balls are soldered on the image sensor 320, so as to achieve the electrical connection between the image sensor 320 and the conductor 313 through solder balls and ensure the reliability of the electrical connection.

Referring to FIG. 5, after the image sensor 320 is provided with the conductive particles 340, the image sensor 320 can be assembled on the base 310 and corresponding processing (e.g., reflow soldering, etc.) is performed, so as to achieve reliable electrical connection between the image sensor 320 and the conductor 313. In some embodiments, the image sensor 320 provided with the conductive particles 340 is attached to the base 310 using a flip-chip packaging process. Flip chip is to connect the conductive contacts of the chip to the circuit of the substrate, circuit board and other devices. During the connection process, since bumps of the chip is connected downward, it is called flip chip. Electronic devices manufactured by flip-chip packaging process have high integration, small volume, and high performance. After the image sensor 320 provided with the conductive particles 340 is attached to the base 310 using the flip-chip packaging process, the image sensor 320 can form a reliable electrical connection with the base 310 after corresponding processing. The image sensor 320 can then be electrically connected to an external circuit board through the conductor 313 to achieve communication with the external circuit board.

The image sensor 320 may also be referred to as a photosensitive chip or a photosensitive element, which can convert received optical signals into electrical signals. An object of the present disclosure is to provide a base, an image acquisition module, and a camera module that can improve assembly accuracy and yield, and does not limit the specific type of image sensor 320, so any type of photoelectric conversion device that can capture optical signals and generate electrical signals can be applied to the present application. As an example, the image sensor 320 may include, but is not limited to, CCD (Charged Coupled Device), CMOS (Complementary Metal-Oxide Semiconductor), CIS (Contact Image Sensor).

Further, referring to FIG. 10, the second side 310b of the base 310 may be provided with a second mounting groove 310e, which is spaced apart from the first mounting groove 310d. The image acquisition module 300 includes electronic components 330 provided in the second mounting groove 310e and electrically connected to the conductor 313. Specifically, the second side 310b of the base 310 may be provided with two or more spaced-apart second mounting grooves 310e, and two or more second mounting grooves 310e may be provided surrounding a periphery of the first mounting groove 310d. Each second mounting groove 310e is spaced apart from the first mounting groove 310d. Each second mounting groove 310e can be mounted with one or more electronic components 330 such as resistors, capacitors, etc., so that the electronic components 330 are physically isolated from a mounting area of the image sensor 320. With this structure, the mounting area of the image sensor 320 can be reduced, which can effectively prevent dust and other foreign objects from polluting the mounting area of the image sensor 320 during the mounting process of the electronic components 330, thereby improving the yield of the product.

Referring to FIG. 6, in the process of assembling the electronic components 330 on the base 310, solder paste can be injected into the base 310 first, and the electronic components 330 can be attached to the base 310, and the electronic components 330 can be fixed to the base 310 through reflow soldering, and the reliability of the electrical connection between the electronic components 330 and the conductor 313 is ensured. Further, in the embodiment where the image sensor 320 is soldered with solder balls, since both the image sensor 320 and the electronic components 330 are electrically connected to the conductor 313 of the base 310 using tin, solder paste is injected into the base 310 and the electronic components 330 are attached to the base 310, and after the image sensor 320 provided with solder balls is assembled on the base 310, reflow soldering can be performed uniformly, so that the electronic components 330 and the image sensor 320 can form a reliable electrical connection with the conductor 313 of the base 310. The processing method can save processing steps and improve processing efficiency.

Referring further to FIG. 10, the base 310 may include a first end 310f and a second end 310g opposite to each other. The first end 310f and the second end 310g are located between the first side 310a and the second side 310b. The conductor 313 is exposed to the first mounting groove 310d, the second mounting groove 310e, the first end 310f, and the second end 310g. The conductor 313 exposed to the first mounting groove 310d can facilitate the electrical connection between the image sensor 320 and the conductor 313. The conductor 313 exposed to the second mounting groove 310e can facilitate the electrical connection between the electronic component 330 and the conductor 313. The conductor 313 exposed to the first end 310f and the second end 310g facilitates the electrical connection between the acquisition module 300 and the external circuit.

In some embodiments, the first side 310a of the base 310 may also be provided with a third mounting groove 310h, and the through hole 310c extends to a bottom of the third mounting groove 310h, that is, the through hole 310c is in communication with the third mounting groove 310h. The image acquisition module 300 includes a filter 350 embedded in the third mounting groove 310h and covering the other end of the through hole 310c. In other words, in this embodiment, the base 310 may be provided with the first mounting groove 310d and the third mounting groove 310h at opposite ends of the through hole 310c, respectively. The first mounting groove 310d is configured to mount the image sensor 320, and the third mounting groove 310h is configured to mount the filter 350. A shape of the third mounting groove 310h cooperates with a shape of the filter 350. For example, in the embodiment where the filter 350 is in the shape of a rectangular block, the third mounting groove 310h is shaped as substantially rectangular, that is, the cross-section of the third mounting groove 310h is rectangular. The third mounting groove 310h facilitates the assembly and positioning of the filter 350 on the base 310.

In some embodiments, in an end of the through hole 310c for assembling the filter 350, that is, in the third mounting groove 310h, the reliable fixation of the filter 350 on the base 310 can be achieved after the operations of drawing glue, pasting the filter 350, baking and curing, centrifugal cleaning, and drying are sequentially performed. In an embodiment, the first side 310a of the base 310 is provided with a limiting structure 31 la such as a positioning boss, the third mounting groove 310h may be provided on the limiting structure 311a such as a positioning boss, as shown in FIG. 11.

In the above-mentioned image acquisition module 300, the conductor 313 configured to be electrically connected to the image sensor 320 is injection molded or integrally formed with the base 310, and the lens holder 100 and the image sensor 320 can be assembled on the base 310. Compared with the FPC, the base 310 has stronger structural rigidity, and a surface flatness, a position accuracy, etc. of the base 310 can be easily ensured. When the image sensor 320 and the lens holder 100 are assembled on the base 310, higher assembly accuracy can be obtained. Compared with the structure in which the image sensor 320 is packaged on the FPC and the lens holder 100 is stacked on the FPC in the related art, the above-mentioned image acquisition module 300 has a higher integration, which can reduce the investment in high-precision production equipment, and has fewer production processes, lower quality control difficulties and lower costs. Since the image sensor 320 is electrically connected to the conductor 313 that is injection molded or integrally formed with the base 310, this configuration simplifies the assembly and electrical connection process of the image sensor 320 and the base 310, and can ensure the reliability of the electrical connection between the image sensor 320 and the base 310. The conductor 313 may be made of lower-cost materials such as the copper foil 30. Compared with the high-purity gold wire of FPC, the conductor 313 has better structural stability and lower cost, and the reliability of the electrical connection of the image sensor 320 can be ensured.

In the embodiment of the present disclosure, since the FPC is no longer used as an assembly substrate of the image sensor 320 and the lens holder 100, an expensive nickel-palladium-gold FPC material can be saved, a cost of the product is greatly reduced, a performance is greatly improved, and a higher cost performance and market competitive advantage can be obtained.

Since a gold wire connection method between the image sensor 320 and the FPC is omitted, when the image acquisition module 300 of the present disclosure is adopted, the electronic components 330 (capacitors, resistors, image sensors 320, etc.) are electrically connected through the conductor 313. The connection method can shorten a circuit length, effectively reduce electrical impedance and signal interference, and further improve the performance and stability of the product.

The processing process of the image acquisition module 300 of the present disclosure is further optimized, and a large number of assembly processes that need precision equipment or imported equipment to complete are reduced, the equipment input cost and labor cost are greatly reduced, and the production efficiency is greatly improved.

During the production and processing process of the image acquisition module 300, due to the guarantee of the structural rigidity of the base 310 and the improvement of the positional accuracy, the cumulative tolerance of the process can be further reduced, so as to improve the processing and assembly accuracy of the product, so that the yield of the product is greatly improved.

Further, as for the image acquisition module 300 provided in the embodiment of the present disclosure, the forming mold of the base 310 can be adaptively adjusted, such that multiple bases 310 or even multiple image acquisition modules 300 can be formed at one time, so as to achieve large-scale, batch and standardized production operations to achieve standardized packaging of the camera module 10 for long-order, long-term, non-line change mass production, so that product stability, yield and production efficiency are greatly improved.

Since the conductor 313 is injection molded or integrally formed with the base 310, the conductor 313 can have a certain structural rigidity, or a male structure for electrical connection can be formed on the base 310 by welding, etc., and the external circuit board only needs to be provided with a corresponding female base structure to achieve the convenient insertion and assembly of the image acquisition module 300 and the external circuit board, so as to shorten the path of electrical connection, and improve the efficiency of assembly and the working performance.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present invention, but are not intended to limit the protection scope of the present invention. Any variation or replacement readily figured out by a person skilled in the art within the technical scope disclosed in the present invention shall all fall within the protection scope of the present invention.

1. An image acquisition module, comprising:
a base comprising a base body and a conductor injection-molded on the base body, the base being configured to assemble a lens holder; and
an image sensor provided on the base and electrically connected to the conductor.

2. The image acquisition module according to claim 1, wherein the base comprises opposite first and second sides, the base is provided with a through hole extending from the first side to the second side, the first side is configured to assemble the lens holder, and the image sensor is provided on the second side and covers one end of the through hole.

3. The image acquisition module according to claim 2, wherein the second side is provided with a first mounting groove, the through hole extends to a bottom of the first mounting groove, and the image sensor is embedded in the first mounting groove.

4. The image acquisition module according to claim 3, wherein the second side is provided with a second mounting groove spaced apart from the first mounting groove, the image acquisition module comprises an electronic component provided in the second mounting groove and electrically connected to the conductor.

5. The image acquisition module according to claim 4, wherein the base comprises opposite first and second ends, the first end and the second end are located between the first side and the second end, the conductor is exposed to the first mounting groove, the second mounting groove, the first end, and the second end.

6. The image acquisition module according to claim 2, wherein the first side is provided with a third mounting groove, the through hole extends to a bottom of the third mounting groove, the image acquisition module comprises a filter embedded in the third mounting groove and covering the other end of the through hole.

7. The image acquisition module according to claim 6, wherein the base is provided with a limiting structure on the first side, the limiting structure is configured to assemble and position the lens holder, and the third mounting groove is provided on the limiting structure.

8. The image acquisition module according to claim 1, wherein the conductor comprises a wire substrate formed by bending and a plating layer plated on a surface of the wire substrate, the plating layer is made of at least nickel and gold.

9. A camera module, comprising:
a lens holder; and
the image acquisition module according to claim 1.

10. The camera module according to claim 9, wherein the lens holder comprises a lens barrel and a mounting base sleeved on the lens barrel, and the mounting base is connected to the base.

11. An image acquisition module, comprising:
a base comprising a base body and a conductor integrally formed with the base body, the base being configured to assemble a lens holder; and
an image sensor provided on the base and electrically connected to the conductor.

12. The image acquisition module according to claim 11, wherein the base comprises opposite first and second sides, the base is provided with a through hole extending from the first side to the second side, the first side is configured to assemble the lens holder, and the image sensor is provided on the second side and covers one end of the through hole.

13. The image acquisition module according to claim 12, wherein the second side is provided with a first mounting groove, the through hole extends to a bottom of the first mounting groove, and the image sensor is embedded in the first mounting groove.

14. The image acquisition module according to claim 13, wherein the second side is provided with a second mounting groove spaced apart from the first mounting groove, the image acquisition module comprises an electronic component provided in the second mounting groove and electrically connected to the conductor.

15. The image acquisition module according to claim 12, wherein the first side is provided with a third mounting groove, the through hole extends to a bottom of the third mounting groove, the image acquisition module comprises a filter embedded in the third mounting groove and covering the other end of the through hole.

16. The image acquisition module according to claim 15, wherein the base is provided with a positioning boss on the first side, the positioning boss is configured to assemble and position a positioning groove of the lens holder, the third mounting groove is provided on the positioning boss.

17. The image acquisition module according to claim 11, wherein the conductor comprises a wire substrate formed by bending and a plating layer plated on a surface of the wire substrate, the plating layer is made of at least nickel and gold.

18. A camera module, comprising:
a lens holder; and
the image acquisition module according to claim 11.

19. A base of an image acquisition module, comprising:
a base body and a conductor injection-molded on the base body;
wherein a first side of the base body is configured to assemble a lens holder, a second side of the base body opposite to the first side is configured to dispose an image sensor, and the conductor is configured to be electrically connected to the image sensor and an external circuit.
